(19) United States
(12) Patent Application Publication
(10) Pub. No.: US 2005/0017244 A1
(43) Pub. Date: Jan. 27, 2005

(54) Semiconductor device

(76) Inventors: Randy Hoffman, Corvallis, OR (US); Hai Chiang, Corvallis, OR (US); John Wager, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/763,353

(22) Filed: Jan. 23, 2004

Related U.S. Application Data
(60) Provisional application No. 60/490,239, filed on Jul. 25, 2003.

(51) Int. Cl. H01L 21/00; H01L 29/04

(52) U.S. Cl. 257/72; 438/149; 257/347; 257/43

(57) ABSTRACT

A semiconductor device including a source electrode, a drain electrode and a channel coupled to the source electrode and the drain electrode. The channel is comprised of a ternary compound containing zinc, tin and oxygen. The semiconductor device further includes a gate electrode configured to permit application of an electric field to the channel.

### CROSS-REFERENCE TO RELATED APPLICATION

This application claims priority from copending application Ser. No. 60/490,239 filed on Jul. 25, 2003, which is hereby incorporated by reference herein.

### BACKGROUND

Thin-film transistors and other three-port semiconductor devices typically include three electrodes separated in part by a channel material. In many such devices, one of the electrodes is further separated from the other electrodes by a dielectric material, as is the case with the gate electrode in a thin-film transistor. In a thin-film transistor, and in other transistors having a gate electrode, the voltage applied to the gate electrode controls the behavior of the channel material. Specifically, the applied gate voltage controls the ability of the channel material to permit charge transport through the channel material between the other two electrodes (e.g., a source electrode and drain electrode).

Extensive research has been conducted with respect to the materials used to fabricate the different components in thin-film transistors. Though materials that have been used for thin film transistors may be suitable for many applications, it will in some cases be desirable to have channel layers formed from other materials. Other materials may provide certain performance or processing benefits, result in cost savings and/or provide characteristics that are difficult to achieve otherwise.

### BRIEF DESCRIPTION OF THE DRAWINGS

FIG. 1 depicts an embodiment of an exemplary three-port semiconductor device according to the present description, in the form of a thin-film transistor.

FIG. 2 depicts an embodiment of an exemplary dielectric layer that may be implemented in connection with the three-port semiconductor device of FIG. 1.

FIG. 3 depicts an embodiment of an exemplary display system in which the semiconductor devices of the present description may be employed.

FIG. 4 depicts an exemplary method of using the three-port semiconductor devices of the present description.

FIGS. 5-8 depict further exemplary embodiments of a thin-film transistor according to the present description.

### DETAILED DESCRIPTION

The present description pertains to a system and method involving a multi-port semiconductor device in which a novel configuration is employed in one or more of the charge-carrying portions of the device. The present system and method is applicable to a variety of semiconductor applications, but has proved particularly useful in the context of thin-film transistor (TFT) technologies, and more particularly in TFTs that are at least partially transparent.

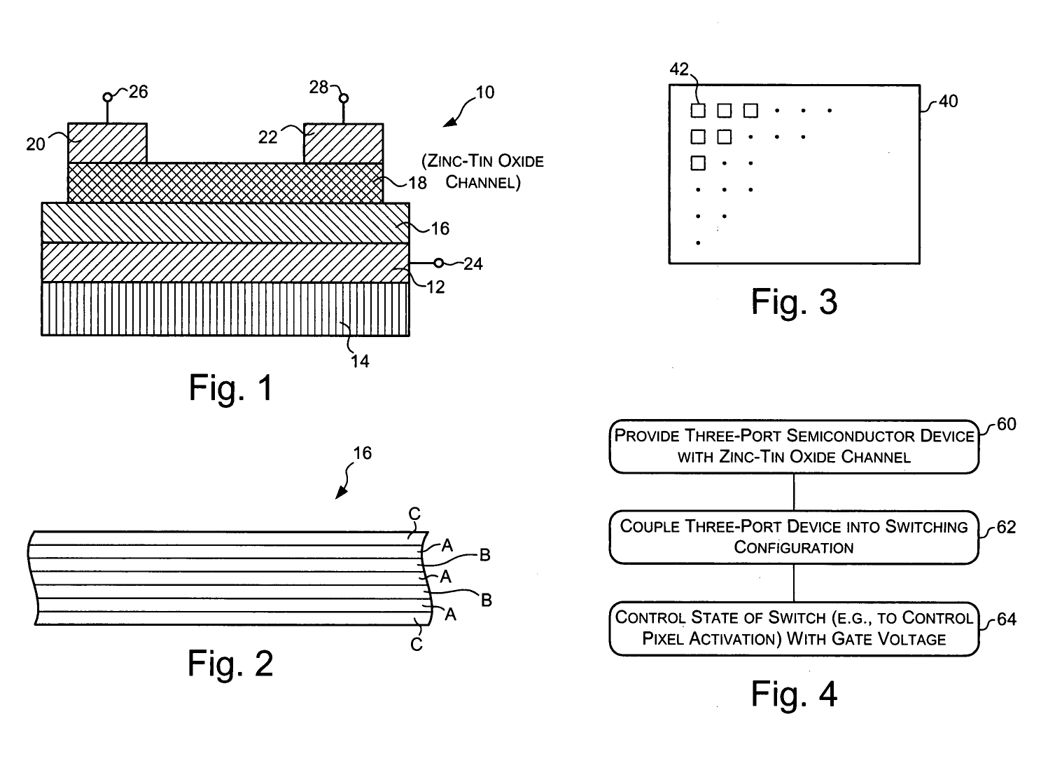

FIG. 1 depicts an exemplary three-port semiconductor device according to the present description, such as thin-film transistor (TFT) 10. As shown, TFT 10 may employ a bottom-gate structure, in which material comprising a gate electrode 12 is disposed adjacent a substrate 14. A dielectric 16 is disposed atop gate 12. A channel layer 18 is interposed between dielectric 16 and source electrode 20 and drain electrode 22. Electrical conditions existing at gate electrode 12 (e.g., a gate voltage applied to port 24) determine the ability of the device to transport charge through channel 18 between source 20 and drain 22 (e.g., as current flowing through the channel between ports 26 and 28).

It will be appreciated that a variety of different fabrication techniques and materials may be employed to fabricate a thin-film transistor, such as that shown in the figure. In the depicted example, substrate 14 may be formed from glass and coated with a material such as indium-tin oxide (ITO) to form the gate electrode. Although the gate electrode and dielectric are depicted as blanket-coated, unpatterned layers in FIG. 1, they may in general be patterned as appropriate. A channel layer is disposed over the dielectric, as will be explained, and indium-tin oxide contacts are disposed for the source and drain electrodes. Regardless of the particular fabrication techniques, the different regions are disposed/configured so that: the source and drain electrodes are physically separate from one another (e.g., separated by the channel material); the three ports (source, drain and gate) are physically separated from each other (e.g., by the dielectric and channel); and the dielectric separates the gate from the channel. Also, as discussed below and shown in the depicted examples, the source and drain are coupled together by the channel.

In addition, the dielectric layer (e.g., dielectric 16) may be formed with alternating layers of different materials, such as AlOₓ and TiO_{y} layers. In particular, as shown in FIG. 2, dielectric layer 16 may include interior layers of type A and type B, where type A is formed from AlOₓ and type B is formed from TiO_{y} (x and y being positive nonzero values), or vice versa. The outer layers (designated with C) may be formed from or coated with a cap layer of Al₂O₃ or another suitable material. Specifically, the dielectric sub-layer immediately adjacent and in contact with gate electrode 12 may be Al₂O₃ and the layer immediately adjacent and in contact with channel 18 may be Al₂O₃.

The ITO source/drain contacts may be deposited via ion beam sputtering, in the presence of argon and oxygen, or through other suitable deposition methods. The source and drain contacts may be disposed via patterning with shadow masks or the like, or through other suitable patterning methods.

As indicated in FIGS. 1 and 4 (FIG. 4 depicts a method to be explained below), channel 18 may be fabricated employing a ternary material containing zinc, tin and oxygen. These more complicated materials (e.g., ternary compounds and materials having more than three elemental components) tend to be less predictable, and often have structures that are much less ordered than binary compounds. Indeed, ternary compounds are often amorphous. Less ordered materials (e.g., amorphous materials) are typically dramatically less efficient at permitting charge transport. For example, amorphous silicon is a very poor semiconductor material, relative to crystalline silicon.

Accordingly, experimental results revealing a high degree of charge mobility in the present ternary channel material were unexpected. Even more unexpected were findings showing adequate charge mobility in certain amorphous zinc-tin oxides.

A variety of zinc-tin oxide materials may be employed within the channel 18 to provide suitable performance in a thin film transistor. Particular formations that have proven useful include ZnSnO₃, Zn₂SnO₄, and/or combinations thereof. More generally, zinc-tin oxide materials of interest herein may comprise the compositional range (ZnO)ₓ(SnO₂)₁₋ₓ, with x between 0.05 and 0.95. While the formulations listed above refer only to stoichiometry (i.e., the relative quantities of zinc, tin, and oxygen in a given zinc-tin oxide material), a variety of morphologies may be obtained depending on composition, processing conditions, and other factors. For example, a zinc-tin oxide film may be either substantially amorphous or substantially poly-crystalline; a poly-crystalline film may furthermore contain a single crystalline phase (e.g., Zn₂SnO₄) or may be phase-segregated so that the channel contains multiple phases (e.g., Zn₂SnO₄, ZnO, and SnO₂). The channel layer 18 may be disposed adjacent dielectric layer 16, through various methods. In the depicted example, the channel is disposed using RF sputtering in an argon-oxygen atmosphere, and patterned using shadow masks.

The zinc-tin oxide semiconductor devices of the present disclosure may be employed in a variety of different applications. One application includes deployment of the zinc-tin oxide channel within thin-film transistors used in an active matrix display, such as that shown at 40 in FIG. 3. In display applications and other applications, since zinc-tin oxide is itself transparent, it will often be desirable to fabricate one or more of the remaining device layers (i.e., source, drain, and gate electrodes) to be at least partially transparent.

Referring still to FIG. 3, Exemplary display 40 includes a plurality of display elements, such as pixels 42, which collectively operate to display image data. Each pixel may include one or more thin-film transistors, such as that described above with reference to FIGS. 1 and 2, in order to selectively control activation of the pixels. For example, each pixel may include three thin-film transistors, one for each of a red, blue and green sub-pixel. In such a display, device 10 (FIG. 1) may be employed as a switch to selectively control activation of the sub-pixel. For example, application of a turn-on voltage at the gate (e.g., applying a HI voltage to gate port 24) may enable current to flow through channel 18 and thereby activate a light-emitting or light-controlling element of the desired hue (e.g., red, green, blue, etc.).

FIG. 4 depicts an example of such a switching method, as may be employed in connection with an active matrix display, or in other settings requiring switching. At 60, the method includes providing a semiconductor device having a channel region formed from compound having zinc, tin and oxygen. At 62, the semiconductor device is coupled into a switching configuration. Referring to the display example, discussed above with respect to FIG. 3, this may include configuring the semiconductor device as a current source switch that controls whether current is applied to a light-emitting display element. In addition, the device may control how much current is supplied, instead of simply acting in a binary mode as an on-off switch. At 64, FIG. 4 depicts an example of the specific control mechanism, namely, that the state of the switch may be controlled in response to a gate voltage. Referring to FIG. 1, such a controlling gate voltage may be applied at port 24 to enable channel 18, and thereby increase the ability of channel 18 to permit charge transport in response to electric potential applied across terminals 26 and 28.

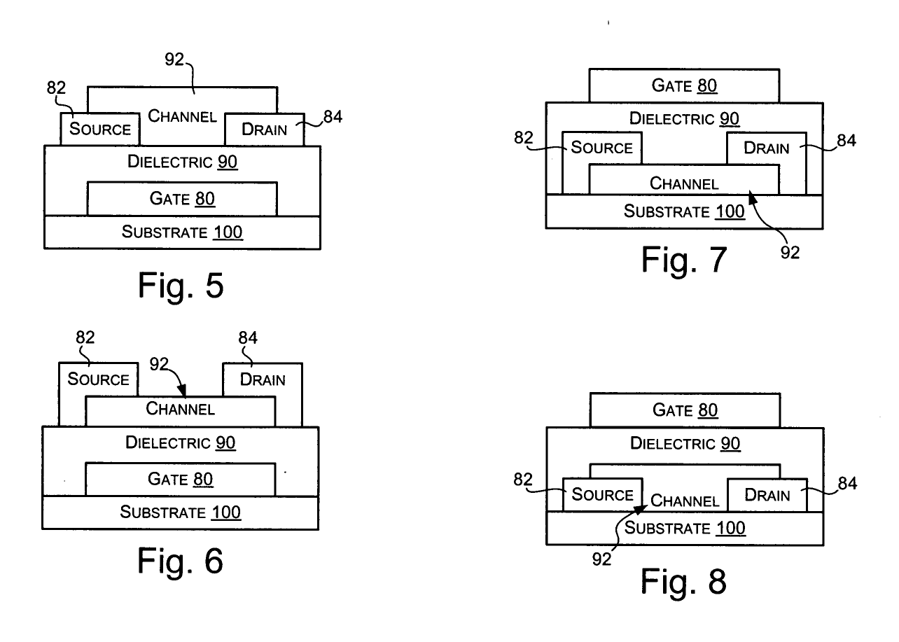

It will be appreciated that various different transistor configurations may be employed in connection with the thin-film devices of the present disclosure. Further exemplary thin-film transistor configurations are shown in FIGS. 5-8. From this and the prior examples, it will be appreciated that typical configurations will include: (a) three primary electrodes, designated in the examples of FIGS. 5-8 as the gate 80, source 82 and drain 84; (b) a dielectric material 90 interposed between gate electrode 80 and each of the source and drain electrodes 82 and 84, such that dielectric material 90 physically separates the gate from the source and drain; (c) a semiconductive material, referred to as the channel 92, disposed so as to provide a controllable electric pathway between the source electrode and the drain electrode. In such a configuration, as known in the transistor arts and discussed with reference to the examples discussed above, voltage applied at gate electrode 80 varies the ability of channel 92 to permit electrical charge to move between the source and drain electrodes. The conductive properties of the channel are thus controlled at least in part through application of a voltage at the gate electrode.

Channel 92 (and the channel of the previous examples) typically is deposited as a thin layer immediately adjacent the dielectric material. Indeed, it will be appreciated that the depictions in the figures are exemplary and are intended to be schematic. The relative dimensions of a device constructed according to the present description, or of its constituent parts, may vary considerably from the relative dimensions shown in the present figures.

Still referring to FIGS. 5-8, regardless of the sequence in which channel 92 and source/drain electrodes 82 and 84 are deposited and patterned, the resulting configuration typically is as described above, namely that the channel is positioned so as to provide a controllable charge pathway between the source and drain electrodes, and dielectric 90 physically separates the channel and gate electrode 80. As previously discussed, it will often be desirable to fabricate the channel from a zinc-tin oxide material.

As in the depicted examples, a thin-film transistor according to the present description may take a variety of different configurations. FIGS. 5 and 6 show exemplary thin-film transistors having a bottom gate configuration. A substrate 100 is employed, though configurations omitting a substrate are possible. Gate electrode 80 is then deposited and patterned as appropriate. Dielectric 90 is deposited on top of the gate electrode and is patterned as appropriate. The channel 92 and source and drain electrodes 82 and 84 are then deposited and patterned as appropriate. In the example of FIG. 5, the source and drain electrodes are formed first, and then channel 92 is deposited on top of the source and drain electrodes. In the example of FIG. 4, channel 92 is deposited first, and the source/drain electrodes are subsequently deposited.

A top gate structure may be employed, as in the examples of FIGS. 7 and 8. In such a configuration, a substrate 100 may again be employed, but the source 82, drain 84 and channel 92 are formed prior to depositing of the layers comprising dielectric 90 and gate electrode 80. In the example of FIG. 7, channel 92 is deposited first as a thin film, and source 82 and drain 84 are deposited and patterned on top of the deposited channel layer. In the example of FIG. 8, channel 92 is deposited on top of the already-formed source and drain electrodes 82 and 84. In either case, dielectric 90 is deposited next and patterned as appropriate, and gate electrode 80 is deposited and patterned on top of dielectric 90.

While the present embodiments and method implementations have been particularly shown and described, those skilled in the art will understand that many variations may be made therein without departing from the spirit and scope defined in the following claims. The description should be understood to include all novel and non-obvious combinations of elements described herein, and claims may be presented in this or a later application to any novel and non-obvious combination of these elements. Where the claims recite “a” or “a first” element or the equivalent thereof, such claims should be understood to include incorporation of one or more such elements, neither requiring nor excluding two or more such elements.

1. A semiconductor device, comprising:
a source electrode;
a drain electrode;
a channel coupled to the source electrode and the drain electrode and comprised of a ternary compound containing zinc, tin and oxygen; and
a gate electrode configured to permit application of an electric field to the channel.

2. The semiconductor device of claim 1, where at least a portion of the channel is formed from a zinc-tin oxide compound having the following stoichiometry: ZnₓSn_{y}O_{z}, where x, y and z have positive non-zero values.

3. The semiconductor device of claim 2, where the zinc-tin oxide compound has the following stoichiometry: ZnSnO₃.

4. The semiconductor device of claim 2, where the zinc-tin oxide compound has the following stoichiometry: Zn₂SnO₄.

5. The semiconductor device of claim 2, where the zinc-tin oxide compound has the following stoichiometry: (ZnO)ⱼ(SnO₂)₁₋ⱼ, where j is between 0.05 and 0.95.

6. The semiconductor device of claim 2, where the zinc-tin oxide compound is substantially amorphous.

7. The semiconductor device of claim 2, where one or more of the source, drain, and gate electrodes is fabricated so as to be at least partially transparent.

8. The semiconductor device of claim 2, where the channel further includes phase-segregated ZnO.

9. The semiconductor device of claim 2, where the channel further includes phase-segregated SnO₂.

10. The semiconductor device of claim 1, where one or more of the source, drain, and gate electrodes is fabricated so as to be at least partially transparent.

11. The semiconductor device of claim 1, where the channel is deposited using an RF sputtering process.

12. The semiconductor device of claim 1, where the source electrode and the drain electrode are formed by depositing an indium-tin oxide material and patterning the indium-tin oxide material so that the source electrode and drain electrode are physically separate from one another.

13. The semiconductor device of claim 1, where the gate electrode is physically separated from the channel by a dielectric material.

14. The semiconductor device of claim 1, where the dielectric material is an aluminum-titanium oxide material.

15. The semiconductor device of claim 14, where the dielectric material includes:
a first outer layer immediately adjacent to and in contact with the channel layer;
a second outer layer immediately adjacent to and in contact with the gate electrode, where the first and second outer layers are each formed from Al₂O₃; and
alternating interior layers of AlOₓ and TiO_{y} between the first and second outer layers, where x and y are positive nonzero values.

16. A three-port semiconductor device, comprising:
a source electrode;
a drain electrode;
a gate electrode; and
means for providing a channel disposed between the source electrode and drain electrode, the means for providing a channel configured to permit movement of electric charge therethrough between the source electrode and the gate electrode in response to a voltage applied at the gate electrode, the means for providing a channel formed at least in part from a ternary compound containing zinc, tin and oxygen.

17. The semiconductor device of claim 16, where the means for providing a channel includes means for providing a semiconductor formed from a zinc-tin oxide compound having the following stoichiometry: ZnₓSn_{y}O_{z}, where x, y and z have positive non-zero values.

18. The semiconductor device of claim 17, where the zinc-tin oxide compound has the following stoichiometry: ZnSnO₃.

19. The semiconductor device of claim 17, where the zinc-tin oxide compound has the following stoichiometry: Zn₂SnO₄.

20. The semiconductor device of claim 17, where the means for providing a semiconductor includes a compound that has the following stoichiometry: (ZnO)ⱼ(SnO₂)₁₋ⱼ, where j is between 0.05 and 0.95.

21. The semiconductor device of claim 17, where the means for providing a semiconductor is substantially amorphous.

22. The semiconductor device of claim 17, where one or more of the source, drain, and gate electrodes is fabricated so as to be at least partially transparent.

23. The semiconductor device of claim 16, where the source electrode and the drain electrode are formed by depositing an indium-tin oxide material and patterning the indium-tin oxide material so that the source electrode and the drain electrode are physically separate from one another.

24. The semiconductor device of claim 16, further comprising means for providing a dielectric disposed between and physically separating the gate electrode from the means for providing a channel.

25. A thin-film transistor, comprising:
a gate electrode;
a channel layer formed from a zinc-tin oxide material;
a dielectric material disposed between and separating the gate electrode and the channel layer; and
first and second electrodes spaced from each other and disposed adjacent the channel layer on a side of the channel layer opposite the dielectric material, such that the channel layer is disposed between and electrically separates the first and second electrodes.

26. The thin-film transistor of claim 25, where the thin-film transistor is configured so that the ability of the channel layer to convey electric charge between the first and second electrodes in response to a potential difference applied across the first and second electrodes is dependent upon a gate voltage applied at the gate electrode.

27. The thin-film transistor of claim 25, where at least a portion of the channel layer is formed from a zinc-tin oxide compound having the following stoichiometry: ZnₓSn_{y}O_{z}, where x, y and z have positive non-zero values.

28. The thin-film transistor of claim 27, where the zinc-tin oxide compound has the following stoichiometry: ZnSnO₃.

29. The thin-film transistor of claim 27, where the zinc-tin oxide compound has the following stoichiometry: Zn₂SnO₄.

30. The thin-film transistor of claim 27, where the zinc-tin oxide compound has the following stoichiometry: (ZnO)ⱼ(SnO₂)₁₋ⱼ, where j is between 0.05 and 0.95.

31. The thin-film transistor of claim 27, where the zinc-tin oxide compound is substantially amorphous.

32. The thin-film transistor of claim 27, where one or more of the source, drain, and gate electrodes is fabricated so as to be at least partially transparent.

33. The thin-film transistor of claim 27, where the channel layer further includes phase-segregated ZnO.

34. The thin-film transistor of claim 27, where the channel layer further includes phase-segregated SnO₂.

35. The thin-film transistor of claim 25, where one or more of the source, drain, and gate electrodes is fabricated so as to be at least partially transparent.

36. The thin-film transistor of claim 25, where the channel layer is deposited using an RF sputtering process.

37. The thin-film transistor of claim 25, where the first and second electrodes are formed by depositing an indium-tin oxide material and patterning the indium-tin oxide material so that the first and second electrodes are physically separate from one another.

38. The thin-film transistor of claim 25, where the dielectric material is an aluminum-titanium oxide material.

39. The thin-film transistor of claim 38, where the dielectric material includes:
a first outer layer immediately adjacent to and in contact with the channel layer;
a second outer layer immediately adjacent to and in contact with the gate electrode, where the first and second outer layers are each formed from Al₂O₃; and
alternating interior layers of AlOₓ and TiO_{y} between the first and second outer layers, where x and y are positive nonzero values.

40. A method of controlling an active matrix display, comprising:
providing a three-port semiconductor device, where the semiconductor device includes a zinc-tin oxide channel layer configured to permit charge transport between a source electrode and a drain electrode of the semiconductor device based upon a gate voltage applied to a gate electrode of the semiconductor device; and
selectively controlling activation and deactivation of a pixel of the active matrix display by selectively controlling the gate voltage.

41. The method of claim 40, where selectively controlling activation and deactivation of the pixel includes turning on the pixel in response to an increase in current flowing between the source electrode and the drain electrode through the zinc-tin oxide material.

42. The method of claim 41, where selectively controlling activation and deactivation of the pixel includes increasing voltage at the gate electrode so as to enable the channel layer and thereby produce the increase in current.

43. A semiconductor-based switching method, comprising:
selectively switching a semiconductor device having a zinc-tin oxide charge-transport channel layer between an activated state and a deactivated state, where placing the device into the activated state includes:
causing voltage at a gate electrode of the semiconductor device to be at or above a turn-on voltage, to thereby increase the ability of the charge-transport channel layer of the semiconductor device to carry charge between a source electrode and a drain electrode of the semiconductor device,
and where placing the device into the deactivated state includes causing voltage at the gate electrode to be at a turn-off voltage, to thereby inhibit the ability of the charge-transport channel layer to carry charge between the source electrode and the drain electrode.

44. A method of making a thin-film transistor, comprising:
providing a substrate;
depositing a gate electrode on the substrate;
depositing a dielectric material on the gate electrode;
depositing a channel layer on the dielectric material, such that the dielectric material is disposed between the channel layer and the gate electrode, where the channel layer is at least partially formed from a ternary compound containing zinc, tin and oxygen; and
forming first and second electrodes adjacent the channel layer so that the first and second electrodes contact the channel layer but are physically separate from each other, and so that the channel layer separates the first and second electrodes from the dielectric layer.

45. A display, comprising:
a plurality of display elements configured to operate collectively to display images, where each of the display elements includes a semiconductor device configured to control light emitted by the display element, the semiconductor device including:
a source electrode;
a drain electrode;
a channel coupled to the source electrode and the drain electrode and comprised of a ternary compound containing zinc, tin and oxygen; and
a gate electrode configured to permit application of an electric field to the channel.

46. The display of claim 45, where at least a portion of the channel of the semiconductor device is formed from a zinc-tin oxide compound having the following stoichiometry: ZnₓSn_{y}O_{z}, where x, y and z have positive non-zero values.

47. The display of claim 46, where the zinc-tin oxide compound has the following stoichiometry: ZnSnO₃.

48. The display of claim 46, where the zinc-tin oxide compound has the following stoichiometry: Zn₂SnO₄.

49. The display of claim 46, where the zinc-tin oxide compound has the following stoichiometry: (ZnO)ⱼ(SnO₂)₁₋ⱼ, where j is between 0.05 and 0.95.
